(19) United States
(12) Patent Application Publication
(10) Pub. No.: US 2022/0358269 A1
(43) Pub. Date: Nov. 10, 2022

(54) SIMULATION EXECUTION SYSTEM, SIMULATION EXECUTION METHOD, AND COMPUTER READABLE MEDIUM

(71) Applicant: Mitsubishi Electric Corporation, Tokyo (JP)

(72) Inventors: Takuma ORIMOTO, Tokyo (JP); Hiroki ITO, Tokyo (JP); Michiyasu HIRAMATSU, Tokyo (JP)

(73) Assignee: Mitsubishi Electric Corporation, Tokyo (JP)

(21) Appl. No.: 17/874,765

(22) Filed: Jul. 27, 2022

Related U.S. Application Data
(63) Continuation of application No. PCT/JP2020/012371, filed on Mar. 19, 2020.

(51) Int. Cl. G06F 30/27

(52) U.S. Cl. CPC G06F 30/27

(57) ABSTRACT

A simulation execution unit (124) performs a simulation with a set time step size, using a simulation engine and using input data for a simulation time slot included in a simulation period as input. A model computation unit (123) performs computation with an estimation model using the input data for the simulation time slot as input. An error calculation unit (125) calculates a difference between a simulation execution result of the simulation time slot and a model computation result of the simulation time slot. A time step size determination unit (126) determines a set time step size in a next simulation time slot based on a result error.

### CROSS REFERENCE TO RELATED APPLICATIONS

This application is a Continuation of PCT International Application No. PCT/JP2020/012371 filed on Mar. 19, 2020, which is hereby expressly incorporated by reference into the present application.

### TECHNICAL FIELD

The present disclosure relates to execution of a simulation.

### BACKGROUND ART

In product-embedded software development, processing such as control written in a design model is simulated on a computer. This allows operation verification to be performed before coding. In addition, operation verification can be performed under conditions that are difficult to realize with an actual machine.

When the entire operation can be simulated on a desk by introducing a plant model that simulates behavior of a control target, verification is realized at a lower cost. However, as the model of the simulation target becomes larger, the simulation computation time also increases.

Patent Literature 1 discloses a method for reducing the simulation computation time by utilizing a model that estimates a simulation result. This model is created by analyzing input data, internal data, and output data during execution of a simulation.

### CITATION LIST

### Patent Literature

Patent Literature 1: WO 2018/143019 A1

### SUMMARY OF INVENTION

### Technical Problem

A technique of performing a simulation by linking a plurality of calculation models such as a plant model and a control model makes it possible to check how the environment of a simulation target behaves as a whole, so that the scope of use of a simulator is expanding. In particular, in the calculation of an evaluation function of optimization calculation, a simulator can be utilized for the purpose of deriving an input condition that minimizes resources such as power consumption in the environment of the simulation target.

In the optimization calculation, the calculation is executed to minimize the evaluation function by changing an input value in a specific algorithm. If simulation results are used for the calculation of the evaluation function, a simulation will be performed many times, so that the simulation execution time will be very long.

When a simulation is repeated by changing a condition to be used as input such as in the optimization calculation, it is required to reduce the simulation execution time while guaranteeing the simulation accuracy.

The method of Patent Literature 1 realizes reduction in the simulation execution time by utilizing an estimation model. However, errors in computation results of the estimation model are not taken into consideration, so that the simulation accuracy is not always guaranteed.

An object of the present disclosure is to make it possible to reduce the simulation execution time while guaranteeing the simulation accuracy.

### Solution to Problem

A simulation execution system according to the present disclosure includes
a simulation execution unit to simulate, with a set time step size, operation of a simulation target in a simulation time slot included in a simulation period, using a simulation engine and using input data for the simulation time slot as input, so as to obtain a simulation execution result of the simulation time slot;
a model computation unit to perform computation with an estimation model for estimating a simulation execution result corresponding to input data, using the input data for the simulation time slot as input, so as to obtain a model computation result, which is an estimated simulation execution result of the simulation time slot;
an error calculation unit to calculate, as a result error, a difference between the simulation execution result of the simulation time slot and the model computation result of the simulation time slot; and
a time step size determination unit to determine a set time step size in a next simulation time slot based on the result error.

### Advantageous Effects of Invention

According to the present disclosure, a time step size for a simulation is determined based on a difference between a simulation execution result and a model computation result, so that it is possible to reduce the simulation execution time while guaranteeing the simulation accuracy.

### BRIEF DESCRIPTION OF DRAWINGS

FIG. 1 is a configuration diagram of a simulation execution system 100S in a first embodiment;

FIG. 2 is a flowchart of model generation in the first embodiment;

FIG. 3 is a flowchart of simulation execution in the first embodiment;

FIG. 4 is a flowchart of the simulation execution in the first embodiment;

FIG. 5 is a diagram illustrating a specific example of a result error in the first embodiment;

FIG. 6 is a conceptual diagram of the simulation execution in the first embodiment; and

FIG. 7 is a hardware configuration diagram of a simulation execution apparatus 100 in the first embodiment.

### DESCRIPTION OF EMBODIMENTS

In the embodiments and drawings, the same elements or corresponding elements are denoted by the same reference sign. Description of an element denoted by the same reference sign as that of an element that has been described will be omitted or simplified as appropriate. Arrows in diagrams mainly indicate flows of data or flows of processing.

### First Embodiment

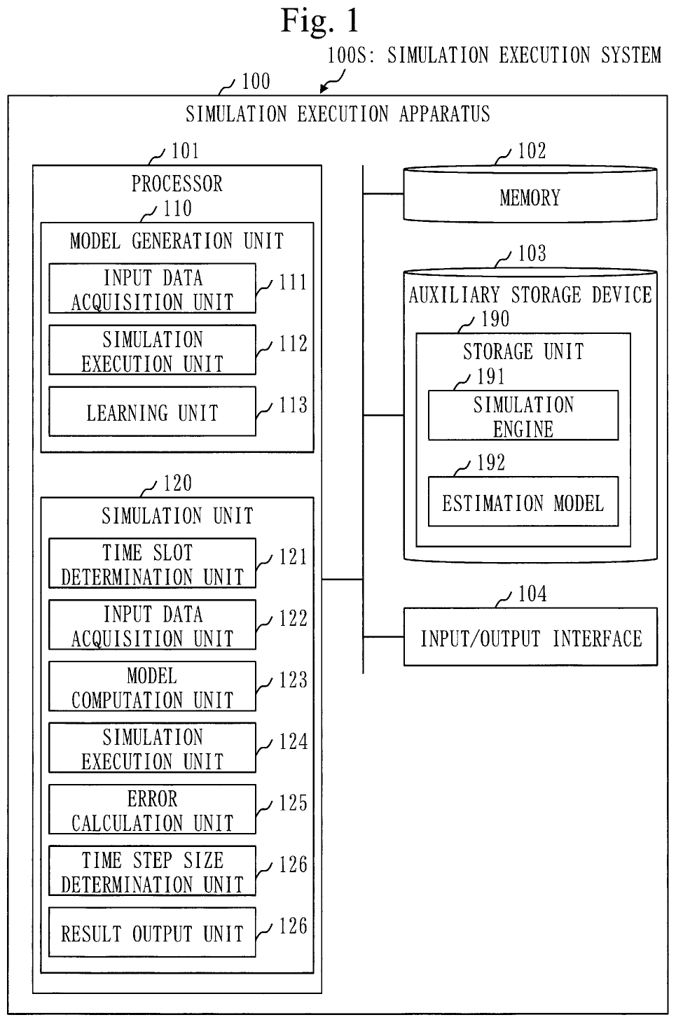

A simulation execution system 100S will be described based on FIGS. 1 to 7.

### Description of Configuration

Based on FIG. 1, a configuration of the simulation execution system 100S and a simulation execution apparatus 100 will be described.

The simulation execution system 100S is realized by the simulation execution apparatus 100. However, the simulation execution system 100S may be realized by two or more apparatuses.

The simulation execution apparatus 100 is a computer that includes hardware such as a processor 101, a memory 102, an auxiliary storage device 103, and an input/output interface 104. These hardware components are connected with one another through signal lines.

The processor 101 is an IC that performs operational processing and controls other hardware components. For example, the processor 101 is a CPU, a DSP, or a GPU.

IC is an abbreviation for Integrated Circuit.

CPU is an abbreviation for Central Processing Unit.

DSP is an abbreviation for Digital Signal Processor.

GPU is an abbreviation for Graphics Processing Unit.

The memory 102 is a volatile or non-volatile storage device. The memory 102 is also called a main storage device or a main memory. For example, the memory 102 is a RAM. Data stored in the memory 102 is saved in the auxiliary storage device 103 as necessary.

RAM is an abbreviation for Random Access Memory.

The auxiliary storage device 103 is a non-volatile storage device. For example, the auxiliary storage device 103 is a ROM, an HDD, or a flash memory. Data stored in the auxiliary storage device 103 is loaded into the memory 102 as necessary.

ROM is an abbreviation for Read Only Memory.

HDD is an abbreviation for Hard Disk Drive.

The input/output interface 104 is a port to which an input device and an output device are connected. For example, the input/output interface 104 is a USB terminal, the input device is a keyboard and a mouse, the output device is a display, and an input/output device is a communication device.

USB is an abbreviation for Universal Serial Bus.

The simulation execution apparatus 100 includes elements such as a model generation unit 110 and a simulation unit 120.

The model generation unit 110 includes elements such as an input data acquisition unit 111, a simulation execution unit 112, and a learning unit 113.

The simulation unit 120 includes elements such as a time slot determination unit 121, an input data acquisition unit 122, a model computation unit 123, a simulation execution unit 124, an error calculation unit 125, a time step size determination unit 126, and a result output unit 127.

These elements are realized by software.

The auxiliary storage device 103 stores a simulation execution program to cause a computer to function as the model generation unit 110 and the simulation unit 120. The simulation execution program is loaded into the memory 102 and executed by the processor 101.

The auxiliary storage device 103 further stores an OS. At least part of the OS is loaded into the memory 102 and executed by the processor 101.

The processor 101 executes the simulation execution program while executing the OS.

OS is an abbreviation for Operating System.

Input data and output data of the simulation execution program are stored in a storage unit 190. In addition, a simulation engine 191, an estimation model 192, and so on are stored in the storage unit 190.

The auxiliary storage device 103 functions as the storage unit 190. However, a storage device such as the memory 102, a register in the processor 101 and a cash memory in the processor 101 may function as the storage unit 190 in place of the auxiliary storage device 103 or together with the auxiliary storage device 103.

The simulation execution apparatus 100 may include a plurality of processors as an alternative to the processor 101. The plurality of processors share the functions of the processor 101.

The simulation execution program can be recorded (stored) in a computer readable format in a non-volatile recording medium such as an optical disc or a flash memory.

### Description of Operation

A procedure for operation of the simulation execution apparatus 100 is equivalent to a simulation execution method. The procedure for the operation of the simulation execution apparatus 100 is also equivalent to a procedure for processing by the simulation execution program.

First, model generation will be described.

The model generation is processing to generate the estimation model 192.

The estimation model 192 is an element for estimating a simulation execution result corresponding to input data to the simulation engine 191. The estimation model 192 is realized by software. The estimation model 192 is also called a learned model or a calculation model.

The simulation engine 191 is an element for simulating operation of a simulation target. The simulation engine 191 is realized by software. The simulation engine 191 is prepared in advance.

An outline of the model generation will be described.

The model generation unit 110 executes the simulation engine 191 using each of a plurality of pieces of input data as input so as to obtain a plurality of simulation execution results. Then, the model generation unit 110 generates the estimation model 192 by using each set of input data and a simulation execution result as learning data and learning a relationship between the input data and the simulation execution result.

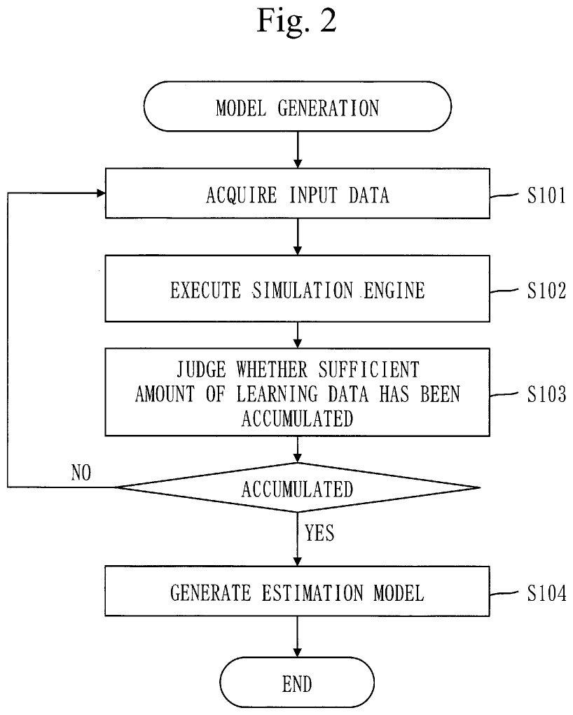

Based on FIG. 2, a procedure for the model generation will be described.

In step S101, the input data acquisition unit 111 acquires input data to the simulation engine 191.

The input data to the simulation engine 191 is acquired as described below.

A plurality of pieces of input data are stored in advance in the storage unit 190. For example, data called a log or a report is used as input data. The input data acquisition unit 111 reads out one piece of input data at a time from the storage unit 190. Each piece of input data may be input into the simulation execution apparatus 100 from an external device via a network, or a user may input each piece of input data into the simulation execution apparatus 100. The input data acquisition unit 111 accepts each piece of input data that has been input.

The input data acquisition unit 111 converts a format of each piece of input data into a format for the simulation engine 191. The converted input data is the input data to the simulation engine 191. The input data to the simulation engine 191 is the input data generated in the format that can be interpreted by the simulation engine 191.

When input data in the format for the simulation engine 191 is given to the simulation execution apparatus 100, it is not necessary to convert the format of the input data.

In step S102, the simulation execution unit 112 sets a simulation period and a time step size in the simulation engine 191.

Then, the simulation execution unit 112 executes the simulation engine 191 using as input the input data acquired in step S101.

The simulation period is the period during which a simulation is to be performed.

The simulation period may be a predetermined period, or may be determined in accordance with a predetermined rule.

The time step size is a unit of time in the simulation. In other words, the time step size is a skip size of time points in the simulation. The shorter the time step size, the higher the simulation accuracy. However, the shorter the time step size, the longer the time required for the simulation.

The time step size may be predetermined time, or may be determined in accordance with a predetermined rule.

The time step size that is set in the simulation engine 191 will be referred to as a “set time step size”.

The simulation engine 191 simulates operation of the simulation target in the simulation period with the set time step size. By this, a simulation execution result is obtained.

The simulation execution result is data including an output value of the simulation target at each time point in the simulation period. For example, the output value of the simulation target represents a state of the simulation target.

The simulation execution unit 112 stores learning data including the input data to the simulation engine 191 and the simulation execution result from the simulation engine 191 in the storage unit 190. The simulation execution unit 112 may include the simulation period and the set time step size in the learning data.

By repeating step S102, the learning data is accumulated in the storage unit 190.

The learning data is used to generate the estimation model 192.

In step S103, the learning unit 113 judges whether a sufficient amount of the learning data has been accumulated.

Specifically, the learning unit 113 compares the number of pieces of the learning data accumulated in the storage unit 190 with a threshold value. If the number of pieces of the learning data is larger than the threshold value (or equal to or larger than the threshold value), the learning unit 113 judges that the sufficient amount of the learning data has been accumulated.

If the sufficient amount of the learning data has been accumulated, processing proceeds to step S104. If the sufficient amount of the learning data has not been accumulated, processing proceeds to step S101.

In step S104, the learning unit 113 uses the accumulated learning data to learn a relationship between the input data to the simulation engine 191 and the simulation execution results from the simulation engine 191. That is, the learning unit 113 analyzes input and output trends in past simulations. By this, the estimation model 192 is generated.

The estimation model 192 can be generated using a publicly known algorithm.

For example, the learning unit 113 generates the estimation model 192 by causing a neural network to learn input data, which is to be an explanatory variable, and output data (simulation execution result), which is to be an objective variable.

For example, the learning unit 113 generates the estimation model 192 by the method disclosed in WO 2018/143019 A1 (Patent Literature 1).

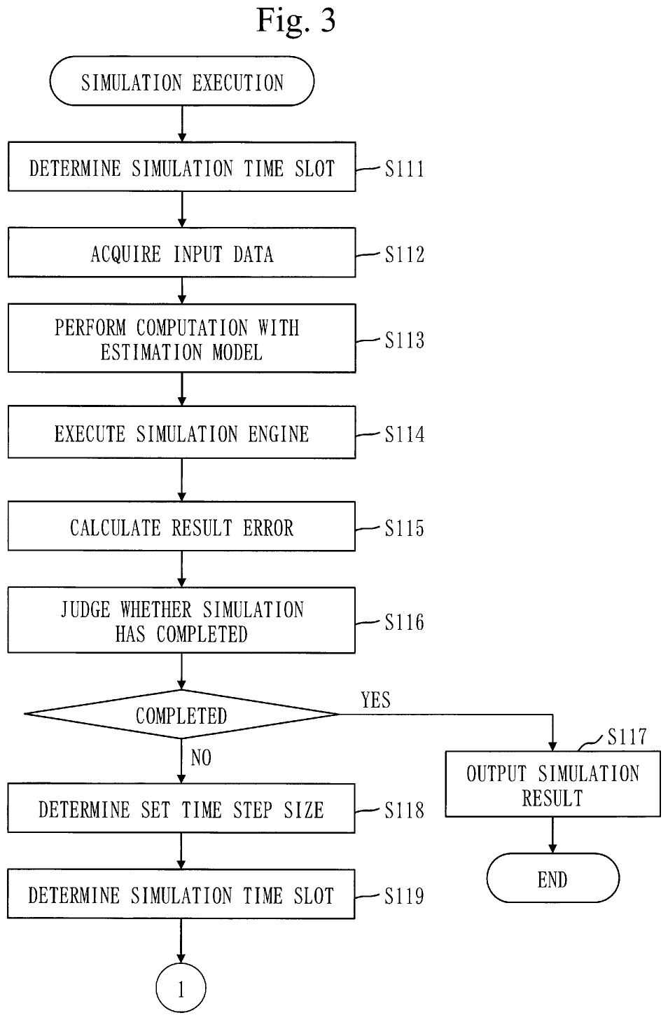

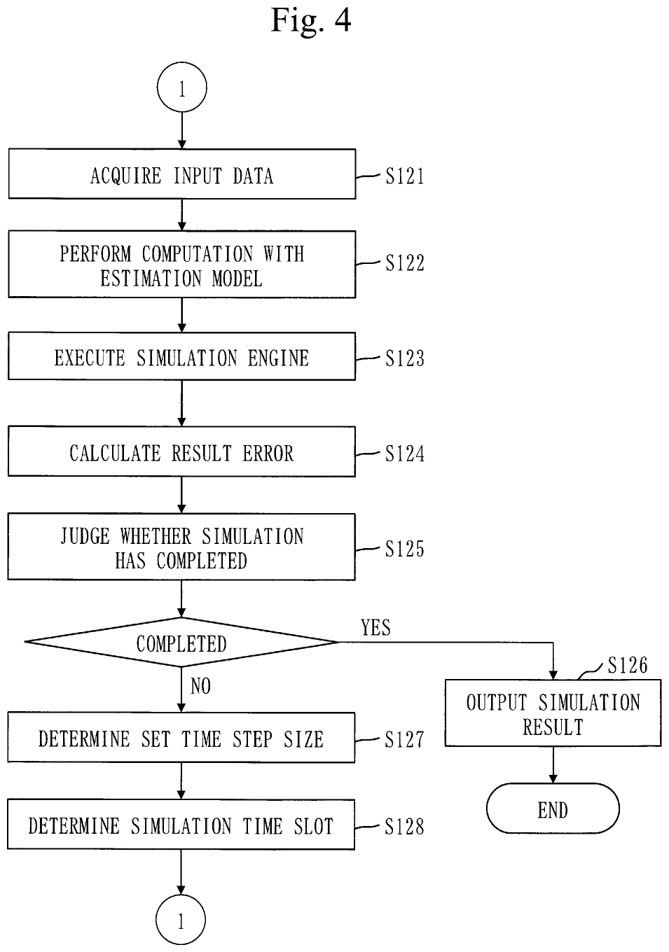

Based on FIGS. 3 and 4, simulation execution will be described.

The simulation execution is processing to execute a simulation using both the simulation engine 191 and the estimation model 192.

In step S111, the time slot determination unit 121 determines an initial simulation time slot.

A simulation time slot is a time slot included in the simulation period.

The initial simulation time slot is determined as described below.

Simulation period data is stored in advance in the storage unit 190. The simulation period data indicates a simulation period and a plurality of simulation time slots. For example, the simulation period data indicates a simulation period of “0 to 180”. The simulation period data also indicates four simulation time slots of “0 to 60”, “60 to 120”, “120 to 150”, and “150 to 180”. The simulation period data may be input into the simulation execution apparatus 100 from an external device via a network, or a user may input the simulation period data into the simulation execution apparatus 100.

The time slot determination unit 121 selects the first simulation time slot “0 to 60” from the simulation time slots indicated in the simulation period data. The selected simulation time slot is the initial simulation time slot.

In step S112, the input data acquisition unit 122 acquires initial input data to the simulation engine 191.

The initial input data is the input data for the initial simulation time slot.

The initial input data is obtained as described below.

Input data is stored in advance in the storage unit 190. The input data acquisition unit 122 reads out the input data from the storage unit 190. The input data may be input into the simulation execution apparatus 100 from an external device via a network, or the user may input the input data into the simulation execution apparatus 100. The input data acquisition unit 122 accepts the input data that has been input.

The input data acquisition unit 122 converts the format of the input data into the format for the simulation engine 191. The converted input data is the initial input data.

When input data in the format for the simulation engine 191 is given to the simulation execution apparatus 100, it is not necessary to convert the format of the input data.

In step S113, the model computation unit 123 sets the initial simulation time slot in the estimation model 192.

Then, the model computation unit 123 performs computation with the estimation model 192 using as input the initial input data.

By this, an estimated simulation execution result of the initial simulation time slot is obtained. The estimated simulation execution result will be referred to as a “model computation result”.

By step S113, an initial model computation result is obtained.

The initial model computation result is the model computation result of the initial simulation time slot.

In step S114, the simulation execution unit 124 sets the initial simulation time slot and an initial set time step size in the simulation engine 191. The initial set time step size is determined in advance.

Then, the simulation execution unit 124 executes the simulation engine 191 using as input the initial input data.

The simulation engine 191 simulates operation of the simulation target in the initial simulation time slot with the initial set time step size.

That is, the simulation execution unit 124 simulates operation of the simulation target in the initial simulation time slot with the initial set time step size, using the simulation engine 191 and using as input the initial input data.

By step S114, an initial simulation execution result is obtained.

The initial simulation execution result is the simulation execution result of the initial simulation time slot.

In step S115, the error calculation unit 125 calculates a difference between the initial simulation execution result and the initial model computation result.

A difference between a simulation execution result and a model computation result will be referred to as a “result error”. The result error is equivalent to an error of a model computation result in relation to a simulation execution result.

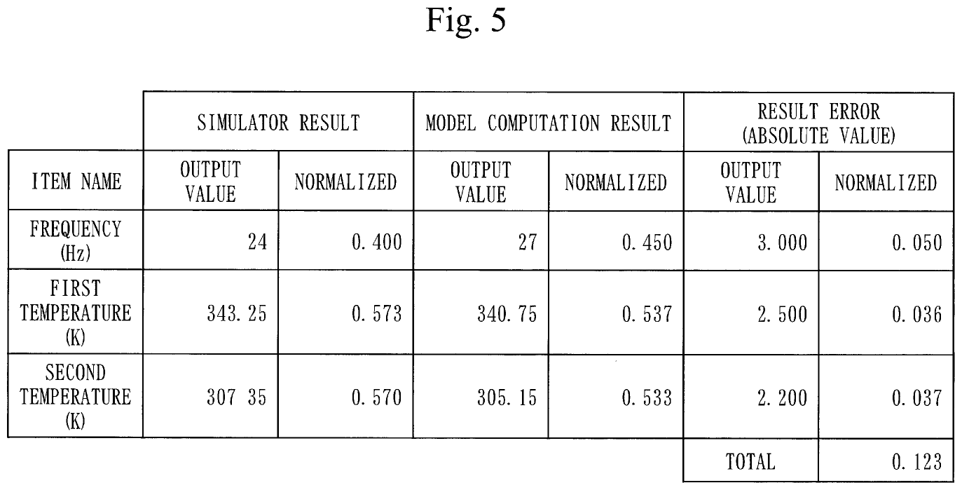

Based on FIG. 5, a specific example of step S115 will be described.

The simulation execution result and the model computation result include output values of items such as “frequency”, “first temperature”, and “second temperature”. Each item for which a result error is to be calculated is specified by the user, for example.

When result errors are to be calculated for a plurality of items, the error calculation unit 125 normalizes the output value of each item. This is because a value range is different for each item. Next, the error calculation unit 125 calculates an absolute value of a difference between the normalized output value of a simulation execution result and the normalized output value of a model computation result for each item. Then, the error calculation unit 125 calculates the sum of calculated differences. The obtained sum is a result error.

In FIG. 5, the difference of “frequency” is 0.050, the difference of “first temperature” is 0.036, and the difference of “second temperature” is 0.037. In this case, the result error is 0.123 (=0.050+0.036+0.037).

The method for calculating a result error is not limited to the above method, and the error calculation unit 125 may calculate a result error using a different algorithm. Other data such as input data may be used to calculate a result error.

Referring back to FIG. 3, the description continues from step S116.

In step S116, the result output unit 127 judges whether the simulation has completed.

Specifically, the result output unit 127 judges whether a simulation completion condition is satisfied. For example, when the simulation completion condition is completion of the simulation of the entire simulation period, the result output unit 127 judges whether the end time point of the initial simulation time slot matches the end time point of the simulation period. The simulation completion condition is determined by the user in advance.

If the simulation has completed, processing proceeds to step S117.

If the simulation has not completed, processing proceeds to step S118. Normally, the simulation does not complete in step S116, and processing proceeds to step S118.

In step S117, the result output unit 127 outputs a result of the simulation execution (simulation result). For example, the result output unit 127 displays the execution result on a display.

The simulation result of step S117 includes the initial simulation execution result and the initial model computation result.

After step S117, processing ends.

In step S118, the time step size determination unit 126 determines a next set time step size based on the initial result error.

The next set time step size is the set time step size in a next simulation time slot.

Specifically, the time step size determination unit 126 determines a shorter set time step size as the result error is larger, and determines a longer set time step size as the result error is smaller.

For example, the time step size determination unit 126 determines the next set time step size as described below.

If the result error is equal to or smaller than 0.05, the time step size determination unit 126 determines the next time step size as 60 seconds.

If the result error is larger than 0.05 and equal to or smaller than 0.10, the time step size determination unit 126 determines the next set time step size as 30 seconds.

If the result error is larger than 0.10, the time step size determination unit 126 determines the next set time step size as 10 seconds.

The method for determining a set time step size is not limited to the above method, and the time step size determination unit 126 may determine a set time step size using a different algorithm.

In step S119, the time slot determination unit 121 determines the next simulation time slot based on the current result error.

Specifically, the time slot determination unit 121 determines the next simulation time slot as described below.

If the result error is smaller than a threshold value, the time slot determination unit 121 determines a time slot with a start time point that is the end time point of the current simulation time slot as the next simulation time slot.

If the result error is larger than the threshold value, the time slot determination unit 121 determines a time slot with a start time point that is a time point earlier than the end time point of the current simulation time slot as the next simulation time slot. That is, the time slot determination unit 121 rolls back the simulation time point.

For example, the time slot determination unit 121 determines the next simulation time slot as described below.

The simulation period data (refer to step S111) indicates four simulation time slots, “0 to 60”, “60 to 120”, “120 to 150”, and “150 to 180”. The current simulation time slot is “60 to 120”. The threshold value is “0.10”.

If the result error is less than 0.10, the time slot determination unit 121 determines the time slot “150 to 180” next to the current simulation time slot as the next simulation time slot.

If the result error is equal to or more than 0.10, the time slot determination unit 121 determines the current simulation time slot “120 to 150” as the next simulation time slot.

The method for determining the next simulation time slot is not limited to the above method, and the time slot determination unit 121 may determine the next simulation time slot using a different algorithm.

The time slot determination unit 121 may determine, as the next simulation time slot, a time slot going back for a longer period of time as the result error is larger.

The time slot determination unit 121 may increase or decrease the number of simulation time slots. If the result error is larger than the threshold value, the time slot determination unit 121 increases the number of simulation time slots. Increasing the number of simulation time slots increases the frequency of checking result errors, so that the accuracy of the simulation execution is guaranteed. If the result error is smaller than the threshold value, the time slot determination unit 121 decreases the number of simulation time slots. Decreasing the number of simulation time slots decreases the frequency of checking result errors, so that the processing time of the simulation execution is reduced.

After step S119, processing proceeds to step S121.

Step S121 and subsequent steps will be described such that “next” in step S118 and step S119 is referred to as “current”.

In step S121, the input data acquisition unit 122 acquires current input data.

The current input data is the input data for the current simulation time slot.

The current input data is acquired as described below.

If the current simulation time slot is the time slot next to the previous simulation time slot, the input data acquisition unit 122 reads out the previous simulation execution result from the storage unit 190, and converts the format of the simulation execution result that has been read out into the format for the simulation engine 191. The converted simulation execution result is the current input data.

If the current simulation time slot is the same time slot as the previous simulation time slot, the input data acquisition unit 122 reads out the previous input data from the storage unit 190. The input data that has been read out is the current input data.

In step S122, the model computation unit 123 sets the current simulation time slot in the estimation model 192.

Then, the model computation unit 123 performs computation with the estimation model 192 using as input the current input data.

By this, a current model computation result is obtained. The current model computation result is an estimated simulation execution result of the current simulation time slot.

In step S123, the simulation execution unit 124 sets the current simulation time slot and the current set time step size in the simulation engine 191.

Then, the simulation execution unit 124 executes the simulation engine 191 using as input the current input data.

The simulation engine 191 simulates operation of the simulation target in the current simulation time slot with the current set time step size.

That is, the simulation execution unit 124 simulates operation of the simulation target in the current simulation time slot with the current set time step size, using the simulation engine 191 and using as input the current input data.

In step S124, the error calculation unit 125 calculates a difference between a current simulation execution result and the current model computation result. That is, the error calculation unit 125 calculates a current result error. The method for calculating a result error is the same as the method in step S115.

In step S125, the result output unit 127 judges whether the simulation has completed. The judgment method is the same as the method in step S116.

If the simulation has completed, processing proceeds to step S126.

If the simulation has not completed, processing proceeds to step S127.

In step S126, the result output unit 127 outputs a result of the simulation execution (simulation result). For example, the result output unit 127 displays the simulation result on the display.

The simulation result of step S126 includes a history of simulation execution results and a history of model computation results.

After step S126, processing ends.

In step S127, the time step size determination unit 126 determines a next set time step size based on the current result error. The determination method is the same as the method in step S118.

In step S128, the time slot determination unit 121 determines a next simulation time slot based on the current result error. The determination method is the same as the method in step S119.

After step S128, processing proceeds to step S121. Then, processing in step S121 and subsequent steps is executed such that “next” in step S127 and step S128 is treated as “current”.

### Description of Implementation Examples

The estimation model 192 may be a model that outputs a computation result and also accuracy (credibility) of the computation result. The time step size determination unit 126 may determine a set time step size based on the accuracy of the computation result. The time step size determination unit 126 determines a longer set time step size as the accuracy is higher, and determines a shorter set time step size as the accuracy is lower.

The simulation execution apparatus 100 may be without the model generation unit 110. In this case, the estimation model 192 is prepared in advance.

The simulation engine 191 and the estimation model 192 may be realized by hardware, or may be realized by a combination of software and hardware.

### Effects of the First Embodiment

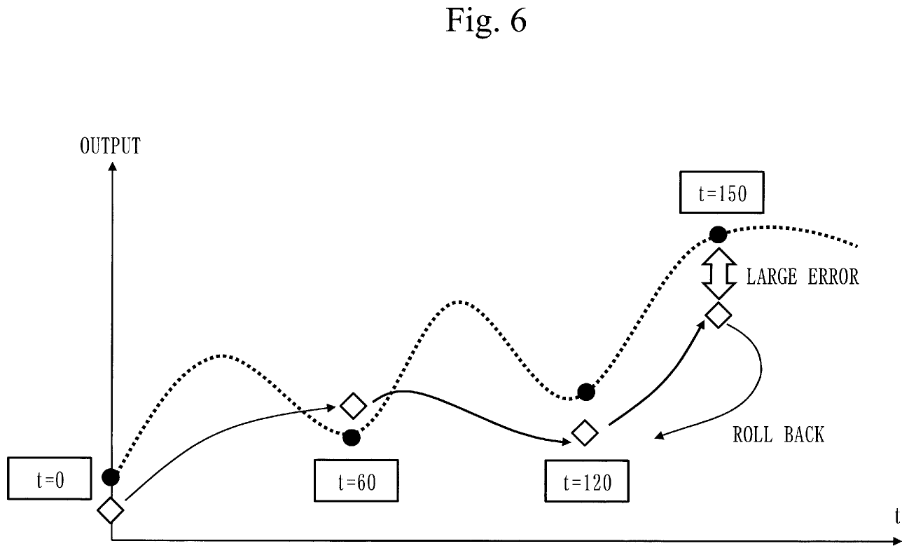

Based on FIG. 6, effects of the first embodiment will be described. A filled circle represents an execution result of the simulation engine 191, and a rhombus represents a computation result of the estimation model 192.

When performing a simulation, the simulation execution apparatus 100 uses a computation result of the estimation model 192 whose processing is relatively faster than that of the simulation engine 191. This allows the processing time of the entire simulation to be reduced.

The simulation execution apparatus 100 compares a computation result of the estimation model 192 with an execution result of the simulation engine 191 at each specific time so as to judge whether the estimation accuracy of the estimation model 192 is high. If an error between the computation result of the estimation model 192 and the execution result of the simulation engine 191 is small, the estimation accuracy of the estimation model 192 is considered to be high. In this case, the simulation execution apparatus 100 lengthens the time step size for the simulation by the simulation engine 191. This allows the processing time of the entire simulation to be reduced. In FIG. 6, the error at t=60 is small. Therefore, the simulation execution apparatus 100 lengthens the time step size for the simulation in the time slot of t=60 to 120. This reduces the simulation time in the time slot of t=60 to 120.

However, if only calculation results of the estimation model 192 are used, the accuracy of simulation results will not be taken into consideration, and unintended results may be obtained. For this reason, the simulation execution apparatus 100 compares the computation result of the estimation model 192 with the execution result of the simulation engine 191 at each specific time so as to judge whether the computation result of the estimation model 192 may be adopted. In FIG. 6, the simulation execution apparatus 100 performs comparison and judgment at each of t=60, t=120, and t=150. If an error between the computation result of the estimation model 192 and the execution result of the simulation engine 191 is large, it is considered that the estimation accuracy of the estimation model 192 has decreased. Therefore, the simulation execution apparatus 100 causes the simulation time point to revert so as to re-perform the simulation. This prevents a decrease in the accuracy of simulation results. In FIG. 6, the error at t=150 is large. Therefore, the simulation execution apparatus 100 rolls back the simulation time point to re-perform the simulation.

As described above, it is possible to reduce the processing time of the entire simulation while guaranteeing the accuracy of simulation results.

### Supplement to the First Embodiment

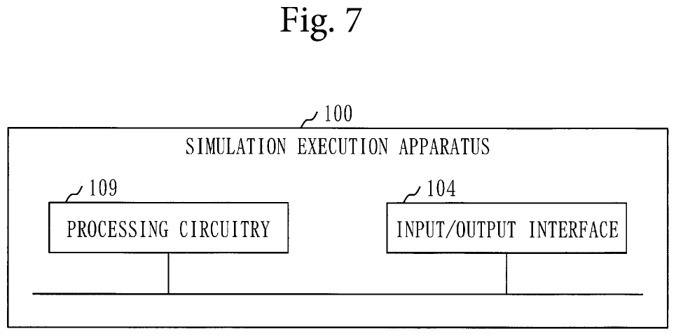

Based on FIG. 7, a hardware configuration of the simulation execution apparatus 100 will be described.

The simulation execution apparatus 100 includes processing circuitry 109.

The processing circuitry 109 is hardware that realizes the model generation unit 110 and the simulation unit 120.

The processing circuitry 109 may be dedicated hardware, or may be the processor 101 that executes programs stored in the memory 102.

When the processing circuitry 109 is dedicated hardware, the processing circuitry 109 is, for example, a single circuit, a composite circuit, a programmed processor, a parallel-programmed processor, an ASIC, an FPGA, or a combination of these.

ASIC is an abbreviation for Application Specific Integrated Circuit.

FPGA is an abbreviation for Field Programmable Gate Array.

The simulation execution apparatus 100 may include a plurality of processing circuits as an alternative to the processing circuitry 109. The plurality of processing circuits share the functions of the processing circuitry 109.

In the processing circuitry 109, some of the functions may be realized by dedicated hardware, and the rest of the functions may be realized by software or firmware.

As described above, the functions of the simulation execution apparatus 100 can be realized by hardware, software, firmware, or a combination of these.

Each embodiment is an example of a preferred embodiment and is not intended to limit the technical scope of the present disclosure. Each embodiment may be implemented partially or may be implemented in combination with another embodiment. The procedures described using the flowcharts or the like may be changed as appropriate.

Each “unit” that is an element of the simulation execution apparatus 100 may be interpreted as “process” or “step”.

### REFERENCE SIGNS LIST

100: simulation execution apparatus, 100S: simulation execution system, 101: processor, 102: memory, 103: auxiliary storage device, 104: input/output interface, 109: processing circuitry, 110: model generation unit, 111: input data acquisition unit, 112: simulation execution unit, 113: learning unit, 120: simulation unit, 121: time slot determination unit, 122: input data acquisition unit, 123: model computation unit, 124: simulation execution unit, 125: error calculation unit, 126: time step size determination unit, 127: result output unit, 190: storage unit, 191: simulation engine, 192: estimation model.

1. A simulation execution system comprising processing circuitry to:
simulate, with a set time step size, operation of a simulation target in a simulation time slot included in a simulation period, using a simulation engine and using input data for the simulation time slot as input, so as to obtain a simulation execution result of the simulation time slot,
perform computation with an estimation model for estimating a simulation execution result corresponding to input data, using the input data for the simulation time slot as input, so as to obtain a model computation result, which is an estimated simulation execution result of the simulation time slot,
calculate, as a result error, a difference between the simulation execution result of the simulation time slot and the model computation result of the simulation time slot, and
determine a set time step size in a next simulation time slot based on the result error.

2. The simulation execution system according to claim 1,
wherein the processing circuitry determines a shorter set time step size as the result error is larger, and determines a longer set time step size as the result error is smaller.

3. The simulation execution system according to claim 1,
wherein the processing circuitry determines the next simulation time slot based on the result error.

4. The simulation execution system according to claim 3,
wherein the processing circuitry determines a time slot with a start time point that is an end time point of the simulation time slot as the next simulation time slot when the result error is smaller than a threshold value, and determines a time slot with a start time point that is a time point earlier than the end time point of the simulation time slot as the next simulation time slot when the result error is larger than the threshold value.

5. The simulation execution system according to claim 1,
wherein the processing circuitry converts a format of input data into a format for the simulation engine,
executes the simulation engine using converted input data as input, and
performs computation with the estimation model using the converted input data as input.

6. The simulation execution system according to claim 1,
wherein the processing circuitry generates the estimation model by executing the simulation engine using each of a plurality of pieces of input data as input so as to obtain a plurality of simulation execution results, and learning a relationship between input data and a simulation execution result using each set of input data and a simulation execution result as learning data.

7. The simulation execution system according to claim 1, wherein the processing circuitry outputs a history of simulation execution results and a history of model computation results.

8. A simulation execution method comprising:
simulating, with a set time step size, operation of a simulation target in a simulation time slot included in a simulation period, using a simulation engine and using input data for the simulation time slot as input, so as to obtain a simulation execution result of the simulation time slot;
performing computation with an estimation model for estimating a simulation execution result corresponding to input data, using the input data for the simulation time slot as input, so as to obtain a model computation result, which is an estimated simulation execution result of the simulation time slot;
calculating, as a result error, a difference between the simulation execution result of the simulation time slot and the model computation result of the simulation time slot; and
determining a set time step size in a next simulation time slot based on the result error.

9. A non-transitory computer readable medium storing a simulation execution program to cause a computer to execute:
a simulation execution process of simulating, with a set time step size, operation of a simulation target in a simulation time slot included in a simulation period, using a simulation engine and using input data for the simulation time slot as input, so as to obtain a simulation execution result of the simulation time slot;
a model computation process of performing computation with an estimation model for estimating a simulation execution result corresponding to input data, using the input data for the simulation time slot as input, so as to obtain a model computation result, which is an estimated simulation execution result of the simulation time slot;
an error calculation process of calculating, as a result error, a difference between the simulation execution result of the simulation time slot and the model computation result of the simulation time slot; and
a time step size determination process of determining a set time step size in a next simulation time slot based on the result error.
